(19) United States
(12) Patent Application Publication
(10) Pub. No.: US 2026/0255569 A1
(43) Pub. Date: Aug. 27, 2026

(54) SEMICONDUCTOR DEVICE, FABRICATION METHOD THEREOF AND MEMORY SYSTEM

(71) Applicant: Yangtze Memory Technologies Co., Ltd., Wuhan (CN)

(72) Inventor: Kan WANG, Wuhan (CN)

(21) Appl. No.: 19/175,282

(22) Filed: Apr. 10, 2025

(30) Foreign Application Priority Data
Feb. 24, 2025 (CN) 202510206275.9

(51) Int. Cl. H10B 12/00

(52) U.S. Cl. CPC H10B 12/00

(57) ABSTRACT

Methods, devices, systems, and techniques for managing conductive structure in semiconductor devices are provided. In one aspect, a semiconductor device includes a memory cell. The memory cell includes a first transistor and a second transistor. The first transistor includes a first semiconductor body extending along a first direction, a first conductive structure that is connected to the first semiconductor body, and a first gate structure that extends along the first direction, where the first semiconductor body is between the first conductive structure and the first gate structure along a second direction perpendicular to the first direction. The second transistor includes a second semiconductor body extending along a first direction, and a second conductive structure, where the second conductive structure is connected to the first conductive structure.

### CROSS-REFERENCE TO RELATED APPLICATIONS

This application claims priority to Chinese Patent Application No. 202510206275.9, filed on Feb. 24, 2025, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical transistors.

### SUMMARY

The present disclosure describes methods, devices, systems and techniques for managing three-dimensional (3D) semiconductor devices, e.g., forming vertical transistors and bit lines of the 3D memory devices.

One aspect of the present disclosure features a semiconductor device. The semiconductor device includes a memory cell, wherein the memory cell includes a first transistor, where the first transistor includes: a first semiconductor body extending along a first direction; a first conductive structure that is connected to the first semiconductor body; a first gate structure that extends along the first direction, where the first semiconductor body is between the first conductive structure and the first gate structure along a second direction perpendicular to the first direction; and a second transistor, where the second transistor includes: a second semiconductor body extending along the first direction; and a second conductive structure, where the second conductive structure is connected to the first conductive structure.

In some implementations, the second transistor further includes a second gate structure that extends along the first direction, where the second semiconductor body is between the second conductive structure and the second gate structure along the second direction.

In some implementations, the first conductive structure and the second conductive structure are between the first semiconductor body and the second semiconductor body along the second direction, and where the first semiconductor body and the second semiconductor body are between the first gate structure and the second gate structure along the second direction.

In some implementations, the first semiconductor body and the second semiconductor body include a metal oxide.

In some implementations, a length of the first conductive structure is greater than a length of the first gate structure along the first direction, and where a length of the second conductive structure is greater than a length of the second gate structure along the first direction.

In some implementations, the first transistor further includes an interconnect layer extending along the second direction, where the interconnect layer is in contact with the first conductive structure and the first semiconductor body along the first direction.

In some implementations, the semiconductor device further includes a first conductive layer stacked on a first end of the second semiconductor body, where the first conductive layer is isolated from the interconnect layer by a separation layer, and where the first conductive layer is in contact with the second semiconductor body.

In some implementations, the second conductive structure is isolated from the first conductive layer by a first isolation structure along the first direction.

In some implementations, the semiconductor device further includes a second conductive layer extending along the second direction, where the second conductive layer is stacked on a second end of the second semiconductor body, where the first end and the second end of the second semiconductor body are on opposite end of the memory cell along the first direction, and where the first semiconductor body and the second semiconductor body are in contact with the second conductive layer along the first direction.

In some implementations, the semiconductor device includes an array of memory cells, and where the array of the memory cells includes rows extending along the second direction and columns extending along a third direction perpendicular to the first direction and the second direction.

In some implementations, the semiconductor device further includes one or more second isolation structures extending along the second direction; a first word line that extends through the one or more second isolation structures along the third direction, where the first word line includes one or more first gate structures of one or more memory cells; and a second word line that extends through the one or more second isolation structures along the third direction, where the second word line includes one or more second gate structures of the one or more memory cells.

In some implementations, the rows of the array of the memory cells are separated from each other by a second isolation structure of the one or more second isolation structures.

In some implementations, second conductive layer includes one or more bit lines that extend along the second direction, and where the one or more bit lines are separated by the one or more second isolation structures along the third direction.

In some implementations, the semiconductor device further includes a stack of the array of the memory cells, where the array of the memory cells are stacked on top of each other along the first direction.

Another aspect of the present disclosure features a method of forming a semiconductor device. The method includes forming a memory cell, where forming the memory cell includes forming a first transistor, where the first transistor includes: a first semiconductor body extending along a first direction; a first conductive structure that is connected to the first semiconductor body; a first gate structure that extends along the first direction, where the first semiconductor body is between the first conductive structure and the first gate structure along a second direction perpendicular to the first direction; and forming a second transistor, where the second transistor includes: a second semiconductor body extending along the first direction; and a second conductive structure, where the second conductive structure is connected to the first conductive structure.

In some implementations, the second transistor of the memory cell includes a second gate structure, where the method includes providing a semiconductor substrate having a first dielectric layer, a second conductive layer, and a second dielectric layer, where the second conductive layer is between the first dielectric layer and the second dielectric layer along the first direction; etching a first portion of the second dielectric layer along the first direction to form a first trench, where the first trench extends along a third direction perpendicular to the first direction and the second direction; depositing a semiconductor layer, a third dielectric layer, and a third conductive layer on an inner wall of the first trench; filling the first trench with a first dielectric material; etching a second portion of the second dielectric layer along the first direction to from second trenches, where the second trenches are separated from the second conductive layer by a remaining portion of the second dielectric layer along the first direction, and where the second trenches extend along the third direction; depositing a second dielectric material on an inner wall of the second trenches to form a fourth dielectric layer; depositing a conductive material on a portion of the fourth dielectric layer to form the first gate structure and the second gate structure of the memory cell; and filling the second trenches with a third dielectric material.

In some implementations, the first semiconductor body and the second semiconductor body are isolated from each other, where the method further includes etching a portion of the semiconductor layer on a bottom of the first trench to separate the semiconductor layer into the first semiconductor body and the second semiconductor body of the memory cell, where the second conductive layer is in contact with the first semiconductor body, the second semiconductor body and the third dielectric layer along the first direction.

In some implementations, the memory cell further includes an interconnect layer, where forming the interconnect layer includes etching a first portion of the first semiconductor body, a portion of the third conductive layer, a portion of the third dielectric layer, and a portion of the fourth dielectric layer along the first direction to form a first hole; depositing a conductive material in the first hole to from the interconnect layer, where the interconnect layer is in contact with the first semiconductor body and the second conductive layer along the first direction; and filling a fourth dielectric material into the first hole to form a separation layer.

In some implementations, the method further includes etching a second portion of the second conductive layer along the first direction to form a second hole; filling the second hole with a fifth dielectric material to form a first isolation structure; and depositing a first conductive layer on an end of the semiconductor substrate to form a third conductive layer, where the third conductive layer is in contact with the second semiconductor body, the first isolation structure, and the separation layer along the first direction.

A further aspect of the present disclosure features a system of a semiconductor device. The system includes a memory device; and a memory controller coupled to the memory device and configured to control the memory device, where the memory device includes a memory cell, where the memory cell includes a first transistor, where the first transistor includes: a first semiconductor body extending along a first direction; a first conductive structure that is connected to the first semiconductor body; a first gate structure that extends along the first direction, where the first semiconductor body is between the first conductive structure and the first gate structure along a second direction perpendicular to the first direction; and a second transistor, where the second transistor includes: a second semiconductor body extending along the first direction; and a second conductive structure, where the second conductive structure is connected to the first conductive structure.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a side view of a cross-section of an example 3D semiconductor device.

FIG. 2A illustrates a cross-section view of an example semiconductor device.

FIG. 2B illustrates a top view of an example semiconductor device.

FIG. 2C illustrates a cross-section view of an example semiconductor device.

FIG. 3A-3Y illustrate an example process of fabricating a semiconductor device.

FIG. 4 illustrated a circuit diagram of an example semiconductor device.

FIG. 5 is a flow chart of another example process of forming a semiconductor device, according to one or more implementations of the present disclosure.

FIG. 6 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to an increased demand for cheaper memory devices with higher density, a memory device (e.g., a DRAM memory) can be formed to have a vertical channel selector tube. The higher density of the memory devices can be achieved by increasing the aspect ratio of the memory device. Currently, the vertical channel selector tube is coupled to a storage structure (e.g., a capacitor) that is configured to store data for the memory device. The storage structure may pose challenges to the increase of the aspect ratio of the memory device due to the limitation of the critical size of the storage structure. Additionally, the storage structure may require additional fabrication steps, which complicates the manufacturing process and increases the fabrication cost of the memory devices. Therefore, a memory device that can solve the aforementioned issues is desirable.

In one or more implementations of the present disclosure, an example semiconductor device is provided. The semiconductor device includes a memory cell, where the memory cell includes a first transistor, where the first transistor includes a first semiconductor body extending along a first direction; a first conductive structure that is electrically connected to the first semiconductor body; a first gate structure that extends along the first direction, where the first semiconductor body is between the first conductive structure and the first gate structure along a second direction perpendicular to the first direction. The memory cell also includes a second transistor, where the second transistor includes a second semiconductor body extending along the first direction; and a second conductive structure, where the second conductive structure is connected to the first conductive structure.

Implementations of the present disclosure can provide one or more of the following technical advantages and/or benefits. For example, the memory device in the present disclosure includes two vertical channel selector tubes, which can be easily scaled down compared to the storage structure. In other words, the two vertical channel selector tubes design in the present disclosure can be fabricated with a higher density, resulting in a higher storage capacitor per unit area of the memory device. Additionally, this approach also allows for easier process implementation and improved control during manufacturing, thereby enhancing manufacturing reliability and increasing the overall production yield.

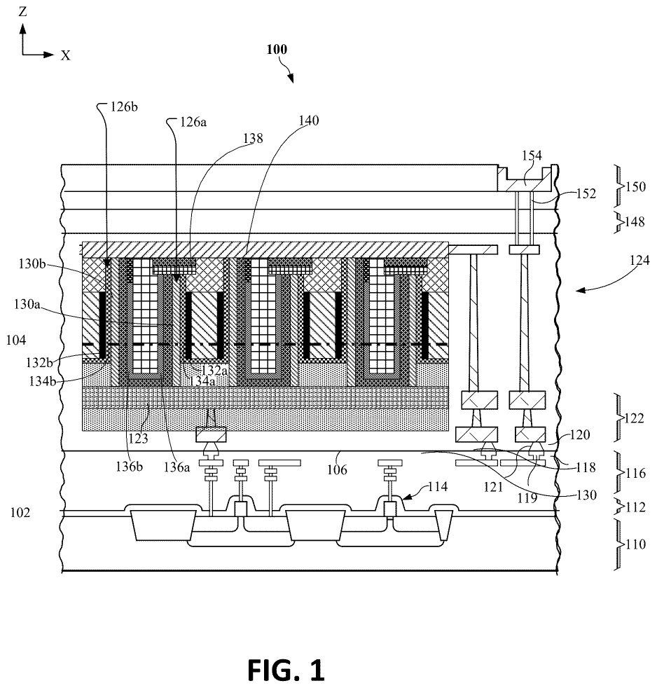

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 there between.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, e.g., as discussed with further details below, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells 124 are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate. In some implementations, the CMOS die 102 can be stacked on either side of the array die 104 along a vertical direction (e.g., the Z direction).

Each of the DRAM cells 124 can include two vertical transistors 126a and 126b. DRAM cell 124 can be a 2T0C cell including two transistors. In some implementations, the transistors can be referring as vertical transistors. The vertical transistors 126a and 126b can be MOSFETs used to switch a respective DRAM cell 124. The first vertical transistor 126a can include a first semiconductor body 130a extending along the Z direction. The second vertical transistor 126b can include a second semiconductor body 130b extending along the Z direction. In some implementations, as shown in FIG. 1, the first semiconductor body 130a and the second semiconductor body 130b are separated along a horizontal direction (e.g., the X direction) perpendicular to the Z direction. In some implementations (not shown in FIG. 1), a portion of the first semiconductor body 130a and a portion of the second semiconductor body 130b are connected together by a connection structure. The portion of the semiconductor bodies 130a and 130b are closer to the bit line 123. In some implementations, each of the semiconductor bodies 130a and 130b has a corresponding gate structures 132a and 132b that is in contact with one side of a corresponding semiconductor bodies 130a and 130b. In some implementations, as shown in FIG. 1, the semiconductor bodies 130a and 130b are separated with the corresponding gate structures 132a and 132b by a dielectric layer along a horizontal direction (e.g., the X direction) perpendicular to the Z direction. For example, the first semiconductor body 130a is separated with the gate structure 132a by a dielectric layer 134a, and the second semiconductor body 130b is separated with the gate structure 132b by a dielectric layer 134b. The semiconductor bodies 130a and 130b can have a cuboid shape or a cylinder shape.

In some implementations, the semiconductor bodies 130a and 130b include metal oxides material including, but not limited to, indium gallium zinc oxide (IGZO), indium tin oxide (ITO), aluminum-doped zinc oxide (AZO), and gallium-doped zinc oxide (GZO). In one example, semiconductor bodies 130a and 130b may include IGZO. In some implementations, gate structures 132a and 132b can include a conductive material including, but not limited to W, Co, Cu, Al, TiN, TaN, polysilicon, silicide, or any combination thereof.

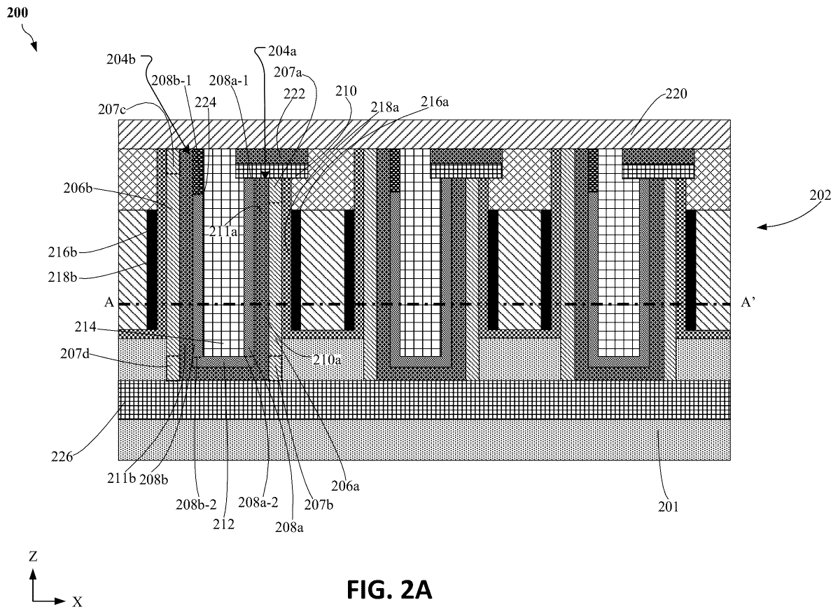

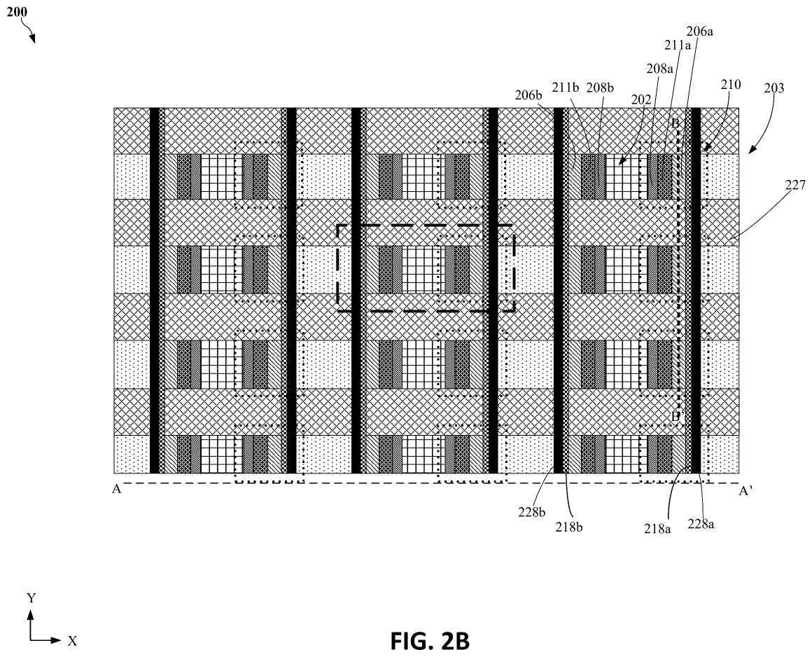

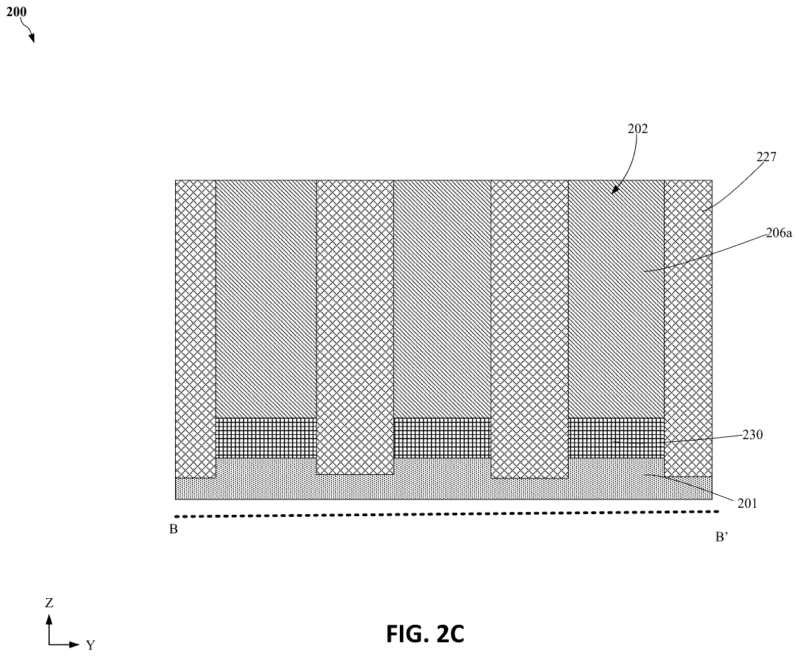

As described above, since the gate structures 132a and 132b may be part of word lines or extend in the word line direction (e.g., the y-direction as shown in FIG. 2B), the second semiconductor structure 104 of the 3D semiconductor device 100 can also include a plurality of word lines each extending in the word line direction (the y-direction). Each of the word lines 132 can be coupled to a row of one of the vertical transistors of the DRAM cells 124. That is, the bit line 123 and the word line 132 can extend in two perpendicular lateral directions, and the semiconductor bodies 130a and 130b can extend in the vertical direction perpendicular to the two lateral directions in which the bit line 123 and the word line 132 extend. Word lines 132 are in contact with word line contacts (not shown). In some implementations, the word lines 132 include conductive materials including, but not limited to W, Co, Cu, Al, TiN, TaN, polysilicon, silicides, or any combination thereof. In some implementations, the word line 132 includes multiple conductive layers, such as a W layer over a TiN layer, as shown in FIG. 1.

The first vertical transistor 126a also includes a first conductive structure 136a electrically connects to the first semiconductor body 130a, and the second vertical transistor 126b also includes a second conductive structure 136b. As shown in FIG. 1, the first conductive structure 136a is connected to the second conductive structure 136b. In some implementations, as shown in FIG. 1, the first conductive structure 136a and the first semiconductor body 130a are connected through an interconnect layer 138. In some implementation (not shown in FIG. 1), the first conductive structure 136a is in electrical contact with the first semiconductor body 130a. In some implementations, the first conductive structure 136a and the second conductive structure 136b are between the first semiconductor body 130a and the second semiconductor body 130b along the X direction. In some implementations, as shown in FIG. 1, the first semiconductor body 130a and the second semiconductor body 130b are between the gate structures 132a and 132b along the X direction. IN some implementations, the semiconductor device 100 further includes a first conductive layer 140 stack on an end of the DRAM cells 124. The first conductive layer 140 is in contact with the second semiconductor body 130b along the Z direction. The first conductive layer 140 and the bit line 123 are on opposite end of the DRAM cells 124 along the Z direction. In some implementations, the DRAM cells can be a 2 transistor 0 capacitor (2T0C) memory cell, where the first vertical transistor 126a can be used as a write transistor that is configured to write data into the second vertical transistor 126b through the gate structure 132a, the first conductive structure 136a, and the second conductive structure 136b. The second vertical transistor 126b can be used as a read transistor that is configured to store the data.

In some implementations, as shown in FIG. 1, the CMOS die 102 can be stacked on a first end of the second semiconductor structure 104, where the first end of the second semiconductor structure 104 is closer to the bit line 123 than the first conductive layer 140 along the Z direction. In some implementations (not shown in FIG. 1), the CMOS die 102 can be stacked on a second end of the second semiconductor structure 104, where the second end of the second semiconductor structure 104 is closer the first conductive layer 140 than the bit line 123 along the Z direction.

In some implementations, second semiconductor structure 104 further includes a substrate 148 disposed above the DRAM cells 124. As described below with respect to the fabrication process, the substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron-or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between semiconductor bodies 130a and 130b may be partially or fully filled with dielectrics. Although not shown, it is further understood that more than one array of DRAM cells 124 may be stacked over one another to vertically scale up the number of DRAM cells 124. For example, the array of the DRAM cells 124 can be stack vertically along the Z direction. Two adjacent array of the DRAM cells 124 can share a first conductive layer 140 or a bit line 123.

FIG. 2A illustrates a cross-section view of an example 3D semiconductor device 200. The semiconductor device 200 can be the semiconductor device 100 of FIG. 1 or a structure at an intermediate fabrication process of the semiconductor device 100 of FIG. 1.

As shown in FIG. 2A, the semiconductor device 200 includes a substrate 201 and memory cell 202 stacked on the substrate 201 along a vertical direction (e.g., the Z direction). The substrate 201 can be any suitable semiconductor substrate having any suitable semiconductor material, such as monocrystalline, polycrystalline or single crystalline semiconductor. For example, the substrate 201 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 201 can be removed from the semiconductor device 200 in a later process of manufacturing the semiconductor device 200.

In some implementations, the memory cell 202 can be similar to, or same as the DRAM cells 124 of FIG. 1. The memory cell 202 includes a first transistor 204a and a second transistor 204b. In some implementations, the first transistor 204a and the second transistor 204b can be refer as vertical transistors. The first transistor 204a includes a first semiconductor body 206a extending along the Z direction. The first semiconductor body 206a can include a first terminal 207a and a second terminal 207b. In some implementations, one of the first terminal 207a and the second terminal 207b can be a source terminal and the other of the first terminal 207a and the second terminal 207b can be a drain terminal.

The first semiconductor body 206a can include a metal oxides material including, but not limited to, indium gallium zinc oxide (IGZO), indium tin oxide (ITO), aluminum-doped zinc oxide (AZO), and gallium-doped zinc oxide (GZO).

In some implementations, the first transistor 204a also includes a first conductive structure 208a having a first end 208a-1 and a second end 208a-2 along the Z direction. In some implementations, first terminal 207a of the first semiconductor body 206a is connected to a first end 208a-1 of the first conductive structure 208a by an interconnect layer 210. The interconnect layer 210 extends along a horizontal direction (e.g., the X direction) perpendicular to the Z direction and is in contact with the first terminal 207a of the first semiconductor body 206a and the first end 208a-1 of the first conductive structure 208a along the Z direction. In some implementations, as shown in FIG. 2A, the first semiconductor body 206a and the first conductive structure 208a are spaced by a first isolation structure 211a.

As shown in FIG. 2A, the second transistor 204b includes a second semiconductor body 206b having a first terminal 207c and a second terminal 207d that are on opposite end of the second semiconductor body 206b along the Z direction. In some implementations, the first semiconductor body 206a is similar to, or same as, the second semiconductor body 206b. The second transistor 204b also includes a second conductive structure 208b having a first end 208b-1 and a second end 208b-2 that are on opposite end of the second conductive structure 208b along the Z direction. As shown in FIG. 2A, the second end 208a-2 of the first conductive structure 208a is connected to the second end 208b-2 of the second conductive structure 208b by a connection structure 212 along the X direction. As shown in FIG. 2A, a cross-section of the first conductive structure 208a, the second conductive structure 208b and the connection structure 212 perpendicular to a second horizontal direction (e.g., the Y direction) perpendicular to the X direction and the Z direction has a U shape. In some implementations, the second semiconductor body 206b and the second conductive structure 208b are spaced from each other by a second isolation structure 211b along the X direction. In some implementations, as shown in FIG. 2A, a portion of the first conductive structure 208a and a portion of the second conductive structure 208b are spaced from each other by a third isolation structure 214. In some implementations, as shown in FIG. 2A, the first semiconductor body 206a and the second semiconductor body 206b are separated from each other along the X direction. In some implementations (not shown in FIG. 2A), the second terminal 207b of the first semiconductor body 206a and the second terminal 207d of the second semiconductor body 206b are connected along the second direction.

As shown in FIG. 2A, the first transistor 204a includes a first gate structure 216a in contact with the first semiconductor body 206a. In some implementations, as shown in FIG. 2A, the first gate structure 216a is in contact with the first semiconductor body 206a through a dielectric layer 218a. The first semiconductor body 206a is between the first gate structure 216a and the first conductive structure 208a along the X direction. In some implementations, the second transistor 204b includes a second gate structure 216b in contact with the second semiconductor body 206b. In some implementations, the second gate structure 216b is in contact with the second semiconductor body 206b through a dielectric layer 218b. The second semiconductor body 206b is between the second gate structure 216b and the second conductive structure 208b along the X direction. In some implementations, as shown in FIG. 2A, the first conductive structure 208a and the second conductive structure 208b are between the first semiconductor body 206a and the second semiconductor body 206b. The first semiconductor body 206a and the second semiconductor body 206b are between the first gate structure 216a and the second gate structure 216b. In some implementations, the memory cell 202 can be used as a 2T0C DRAM cell, where the first transistor 204a can be used as a write transistor that is configured to write data into the second transistor 204b via the first gate structure 216a. The second transistor 204b can be used as a read transistor that stores the data.

In some implementations, a length of the first conductive structure 208a is greater than a length of the first gate structure 216a along the first direction. A difference in length between the first conductive structure 208a and the first gate structure 216a ensures an accurate writing operation of the memory cell 202 through the first gate structure 216a. A length of the second conductive structure 208b is greater than a length of the second gate structure 216b along the first direction. A difference in length between the second conductive structure 208b and the second gate structure 216b ensures an accurate reading operation of the memory cell 202 through the second gate structure 216b.

The semiconductor device 200 also includes a first conductive layer 220 stacked on the first terminal 207c of the second semiconductor body 206b along the Z direction. The first conductive layer 220 extends along the X direction. In some implementations, the first conductive layer 220 is isolated from the interconnect layer 210 by a separation layer 222 along the Z direction. The first conductive layer 220 is in contact with the first terminal 207c of the second semiconductor body 206b along the Z direction. As shown in FIG. 2A, the second conductive structure 208b is isolated from the first conductive layer 220 by a fourth isolation structure 224 along the Z direction. In some implementations, the first conductive layer 220 can be used to apply bias to the second semiconductor body 206b while isolated from the second conductive structure 208b to read the data storage in the second conductive structure 208b during a read operation of the memory cell 202.

As shown in FIG. 2A, the semiconductor device 200 further includes a second conductive layer 226. The second conductive layer 226 extends along the X direction and is stacked on the second terminal 207d of the second semiconductor body. In some implementations, the first conductive layer 220 and the second conductive layer 226 are on opposite end of the memory cell 202 along the Z direction. In some implementations, as shown in FIG. 2A, the second terminal 207b for the first semiconductor body 206a and the second terminal 207d of the second semiconductor body 206b are in contact with the second conductive layer 226 along the Z direction. In some implementations (as shown in FIG. 2B), the second conductive layer can be separated into one or more bit lines along the Y direction.

FIG. 2B illustrates a top view of the example semiconductor device 200 of FIG. 2A along cut line AA′ of FIG. 2A. As shown in FIG. 2B, the semiconductor device 200 can include an array 203 of memory cells arranged in rows extending in the Y direction and columns extending in the X direction. The array 203 of memory cells includes the memory cell 202. In some implementations, the semiconductor device 200 includes one or more fifth isolation structures 227 that extend along the X direction. Each of the rows of the array 203 of memory cells is separated by the one or more fifth isolation structures 227. In some implementations, as shown in FIG. 2B, each of the columns of the array 203 of the memory cell includes a first word line 228a that extends through the one or more fifth isolation structures 227 along the Y direction and a second word line 228b that extends through the one or more fifth isolation structures 227 along the Y direction. The first word line 228a includes one or more first gate structures 216a of one or more first transistors 204a. The second word line 228b includes one or more second gate structures 216b of one or more second transistors 204b. In some implementations, the second conductive layer 226 is separated by the one or more fifth isolation structures 227 along the Y direction in to one or more bit lines 230 that extend along the X direction. Each of the rows of the array 203 of the memory cell is connected to a corresponding bit line 230. In some implementations, as shown in FIG. 2B, a cross-section of the interconnect layer 210 perpendicular to the Z direction can have a square shape. As shown in FIG. 2B, the cross-section of the first semiconductor body 206a and the first conductive structure 208a perpendicular to the Z direction is surrounded by the cross-section of the interconnect layer 210. In some implementations (not shown in FIG. 1B), the semiconductor device can include a stack of arrays 203 of the memory cells. The arrays 203 of the memory cells are stacked on top of each other along the Z direction. In some implementations, two adjacent arrays 203 of the memory cell can share the first conductive layer 220. In some implementations, two adjacent arrays 203 of the memory cell can share the one or more bit lines 230.

FIG. 2C illustrates a cross-section view of the example semiconductor device 200 of FIG. 2B along cut line BB′ of FIG. 2B. As shown in FIG. 2C, one or more fifth isolation structures 227 separates the second conductive layer 226 into one or more bit lines 230. Each of the memory cell is connected to a corresponding bit line 230 along the Z direction. In some implementations, a length of the one or more fifth isolation structures 227 is greater than a length of the first semiconductor body 206a along the first direction to isolate two adjacent memory cell in the array 203 along the Y direction. In some implementations, the one or more fifth isolation structures 227 extend into the substrate 201 along the Z direction to ensure the one or more bit lines 230 are separated from each other along the Y direction.

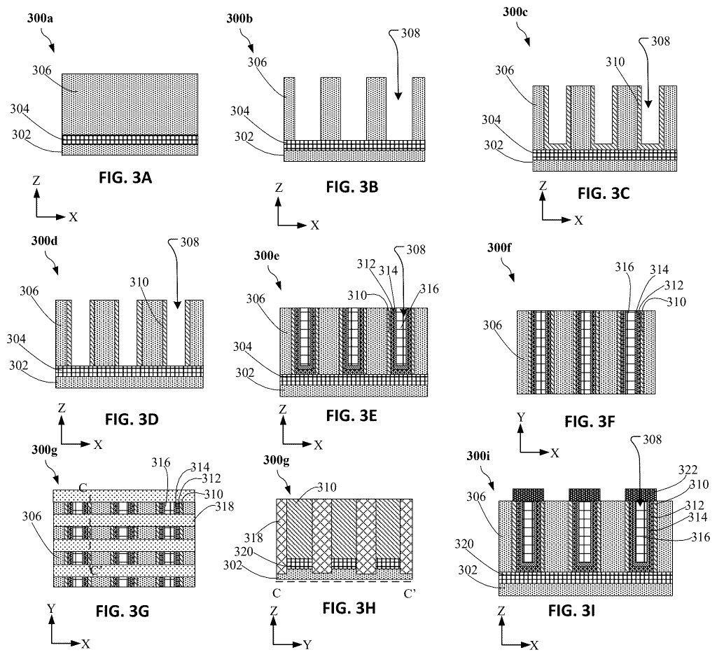

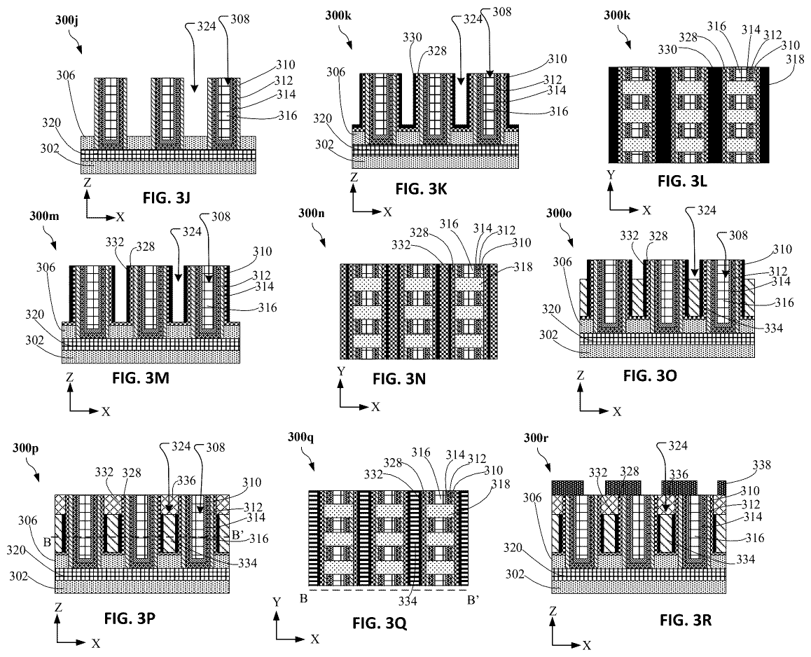

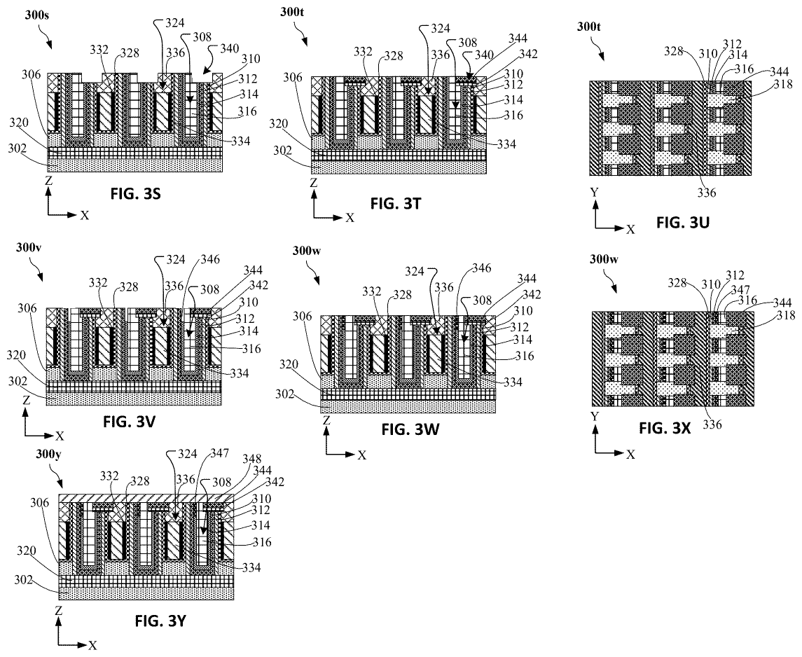

FIG. 3A-3Y illustrate an example process of fabricating a semiconductor device, such as the semiconductor device 200 as illustrated in FIG. 2A. FIG. 3A-3Y show cross sectional views or top views of example semiconductor structures at various stages of the fabrication process.

FIG. 3A illustrates a semiconductor structure 300a. The semiconductor structure 300a includes a substrate 302, a first conductive layer 304, and a first semiconductor layer 306. The first conductive layer 304 is stacked on the substrate 302 along a vertical direction (e.g., the Z direction). The first semiconductor layer 306 is stacked on the first conductive layer 304 along the Z direction. As shown in FIG. 3A, the first conductive layer 304 is between the substrate 302 and the first semiconductor layer 306 along the Z direction.

FIG. 3B illustrates a semiconductor structure 300b, which can be formed by etching a first portion of the first semiconductor layer 306 along the Z direction to form first trenches 308. The first trenches 308 is in contact with the first conductive layer 304 along the Z direction.

FIG. 3C illustrates a semiconductor structure 300c, which can be formed by depositing a metal oxide material on an inner wall of the first trenches 308 to form a layer 310.

FIG. 3D illustrates a semiconductor structure 300d, which can be formed by etching a portion of the layer 310 that is in contact with the first conductive layer 304. A remaining portion of the layer 310 is in contact with the first conductive layer 304 along the first direction.

FIG. 3E illustrates a semiconductor structure 300e, which can be formed by deposition a dielectric material and a conductive material on the inner wall of the first trenches to form a first dielectric layer 312 and a second conductive layer 314. The first dielectric layer 312 is in contact with the first conductive layer 304. The semiconductor structure 300e also includes a first dielectric structure 316, which can be formed by filling a remaining portion of the first trenches 308 by a dielectric material. As shown in FIG. 3E, the second conductive layer 314 is separated from the layer 310 by the first dielectric layer 312.

FIG. 3F illustrates a top view of the semiconductor structure 300e. As shown in FIG. 3E, the second conductive layer 314 is separated from the layer 310 by the first dielectric layer 312 along a horizontal direction (e.g., the X direction) perpendicular to the Z direction. The layer 310, the first dielectric layer 312, the second conductive layer 314, and the first dielectric structure 316 extend along a second horizontal direction (e.g., the Y direction) perpendicular to the X direction and the Z direction.

FIG. 3G illustrates a semiconductor structure 300g, which can be formed by etching a second portion of the first semiconductor layer 306 along the first direction to form second trenches. The second trenches extend along the X direction and separate the layer 310, the first dielectric layer 312, the second conductive layer 314, and the first dielectric structure 316 into one or more segments. The semiconductor structure 300g includes second dielectric structures 318, which can be formed by depositing a dielectric material in the second trenches.

FIG. 3H illustrates a cross-section view of the semiconductor structure 300g of FIG. 3G along cut line CC′ of FIG. 3G. As shown in FIG. 3H, the second dielectric structures 318 extend through the first conductive layer 304 and into the substrate 302 to separate the first conductive layer 304 into multiple segments 320 along the Y direction. Each of the segments 320 of the first conductive layer 304 extends along the X direction.

FIG. 3I illustrates a semiconductor structure 300i, which can be formed by depositing a sacrificial material on the first trenches 308 to form a first sacrificial layer 322.

FIG. 3J illustrates a semiconductor structure 300j, which can be formed by etching a third portion of the first semiconductor layer 306 along the first direction to form second trenches 324. The first sacrificial layer 322 is used to protect the layer 310, the first dielectric layer 312, the second conductive layer 314, and the first dielectric structure 316 during the etching process.

FIG. 3K illustrates a semiconductor structure 300k, which can be formed by depositing a dielectric material and a conductive material on an inner wall of the second trenches 324 to form a second dielectric layer 328 and a third conductive layer 330.

FIG. 3L illustrates a top view of the semiconductor structure 300k. As shown in FIG. 3L, the second dielectric layer 328 and the third conductive layer 330 extend along the Y direction. In some implementations, the second dielectric layer 328 and the third conductive layer 330 extend through the second dielectric structures 318 along the Y direction.

FIG. 3M illustrates a semiconductor structure 300m, which can be form by etching a portion of the third conductive layer 330 on a bottom of the second trenches 324. As shown in FIG. 3M, the third conductive layer 330 in each of the second trenches 324 is separated into two fourth conductive layers 332. The two fourth conductive layers 332 in each of the second trenches 324 are on opposite side walls of the second trench 324.

FIG. 3N illustrates a top view of the semiconductor structure 300n. As shown in FIG. 3N, the two fourth conductive layers 332 in each of the second trenches 324 extend along the Y direction.

FIG. 3O illustrates a semiconductor structure 300o, which can be form by depositing a dielectric material in a portion of the second trenches 324 to from third dielectric structures 334.

FIG. 3P illustrates a semiconductor structure 300p, which can be form by removing a portion of the fourth conductive layers 332 on the side walls of the second trenches and filling a remaining portion of the second trenches 324 to form fourth dielectric structures 336. In some implementations, the fourth dielectric structures 336 can include a dielectric material similar to, or same as the third dielectric structures 334.

FIG. 3Q illustrates a top view of the semiconductor structure 300p along cut line BB′ of FIG. 3P. As shown in FIG. 3Q, the two fourth conductive layers 332 in each of the second trenches 324 are separated by a corresponding third dielectric structures 334 along the X direction.

FIG. 3R illustrates a semiconductor structure 300r, which can be formed by depositing a sacrificial material on a portion of the semiconductor structure 300p to form a second sacrificial layer 338.

FIG. 3S illustrates a semiconductor structure 300s, which can be form by etching a portion of the layer 310, a portion of the first dielectric layer 312, a first portion of the second conductive layer 314, a portion of the first dielectric structure 316, and a portion of the fourth dielectric structures 336 along the Z direction to form third trenches 340. The second sacrificial layer 338 is used to protect a remaining portion of the semiconductor structure 300p during the etching process and is removed after the etching process.

FIG. 3T illustrates a semiconductor structure 300t, which can be form by filling the third trenches 340 with a conductive material and a dielectric material to form an interconnect layer 342 and a third dielectric layer 344. As shown in FIG. 3T, the layer 310 and the second conductive layer 314 are connected to the interconnect layer 342. The third dielectric layer 344 is stacked on top of the interconnect layer 342 along the Z direction.

FIG. 3U illustrates a top view of the semiconductor structure 300t. As shown in FIG. 3U, a cross section of the third dielectric layer 344 perpendicular to the Z direction has a rectangular shape.

FIG. 3V illustrates a semiconductor structure 300v, which can be form by etching a second portion of the second conductive layer 314 along the first direction to form fourth trench 346. As shown in FIG. 3V, the second portion and the first portion of the second conductive layer 314 is on opposite side of the first dielectric structure 316 along the X direction.

FIG. 3W illustrates a semiconductor structure 300w, which can be form by filling a dielectric material in the fourth trench 346 to form a second dielectric structure 347.

FIG. 3X illustrates a top view of the semiconductor structure 300w. As shown by FIG. 3X, the second dielectric structure 347 is between the first dielectric layer 312 and the first dielectric structure 316 along the X direction.

FIG. 3Y illustrates a semiconductor structure 300y, which can be formed by depositing a conductive material on a surface of the semiconductor structure 300w to form a fourth conductive layer 348. In some implementations, as shown in FIG. 3Y, the multiple segments 320 of the first conductive layer 304 and the fourth conductive layer 348 are on opposite end of the layer 310 along the Z direction.

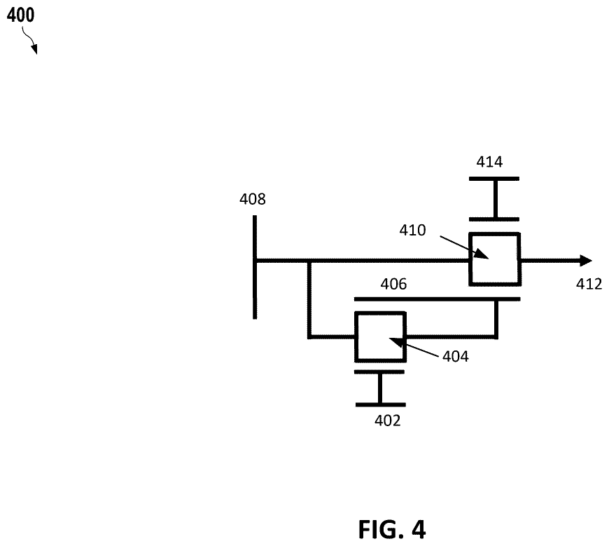

FIG. 4 illustrated a circuit diagram 400 of an example semiconductor device. The example semiconductor device can be the memory cell 202 of FIG. 2A. The memory cell can be configured to perform a write operation or a read operation. During the write operation, a first bias is applied on a first gate structure 402 to turn on a first transistor 404. Data is written into a conductive structure 406 through a bit line 408, where the conductive structure 406 can be used to store the data. The conductive structure 406 is coupled to a second transistor 410, which can be used to perform the read operation. During the read operation, a ground bias is applied on a first conductive layer 412 to turn off the first transistor 404. An electric signal can be read from the first conductive layer 412 by controlling a second bias on a second gate structure 414 coupled to the second transistor 410. When the data stored in the conductive structure 406 is in a ‘0’ state, the second transistor 410 is turned off and a low electrical signal can be read from the first conductive layer 412. When the data stored in the conductive structure 406 is in a ‘1’ state, the second transistor 410 is turned on and a high electrical signal can be read from the first conductive layer 412. In some implementations, the first gate structure 402 can be similar to, or same as the first gate structure 216a of FIG. 2A. The first transistor 404 can be similar to, or same as the first transistor 204a of FIG. 2A. The conductive structure 406 can be similar to, or same as an integrated body of the first conductive structure 208a, the second conductive structure 208b, and the connection structure 212 of FIG. 2A. The bit line 408 can be similar to, or same as the bit line 230 of FIG. 2C. The second transistor 410 can be similar to, or same as the second transistor 204b of FIG. 2A. The first conductive layer 412 can be similar to, or same as the first conductive layer 220 of FIG. 2A. The second gate structure 414 can be similar to, or same as the second gate electrode 216b of FIG. 2A.

In some implementations (not shown in FIG. 4), the circuit diagram 400 of the example semiconductor device comprises the first gate structure 402, the first transistor 404, the conductive structure 406, the bit line 408, the second transistor 410, and the first conductive layer 412. The conductive structure 408 includes the integrated body of the first conductive structure 208a, the second conductive structure 208b, and the connection structure 212 of FIG. 2A. As shown in FIG. 2A, the semiconductor bodies (e.g., the semiconductor bodies 206a and 206b) of the first transistor 404 and the second transistor 410 are electrically connected through the bit line 408. The electric signal can be read from the first conductive layer 412 by controlling a second bias on the first gate structure 402 coupled to the second transistor 410 through the first transistor 404. When the data stored in the conductive structure 406 is in a ‘0’ state, the second transistor 410 is turned off and a low electrical signal can be read from the first conductive layer 412. When the data stored in the conductive structure 406 is in a ‘1’ state, the second transistor 410 is turned on and a high electrical signal can be read from the first conductive layer 412.

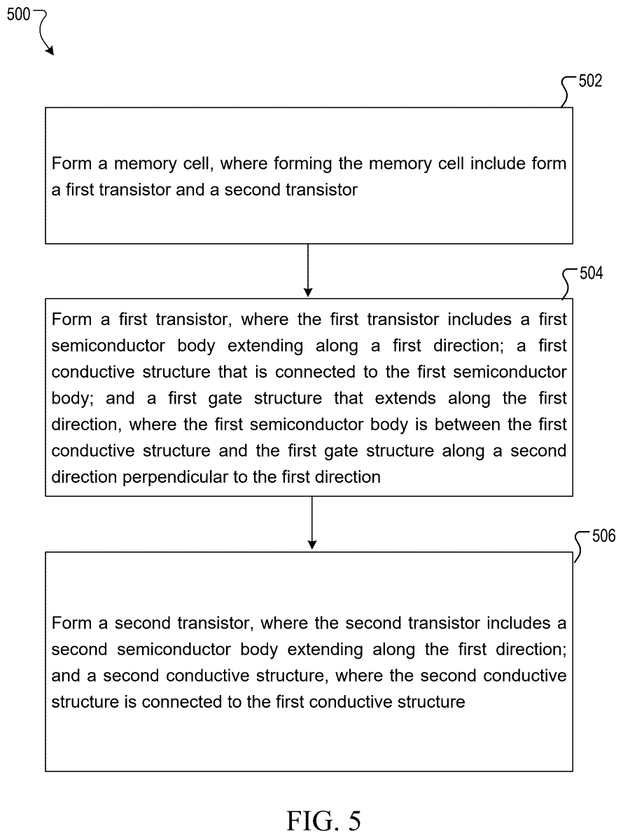

FIG. 5 is a flow chart of an example process 500 of forming a semiconductor device. The semiconductor device can be the semiconductor device 200 of FIG. 2A-2C. The process 500 can be described in view of FIGS. 3A-3Y. The process 500 includes operations (or steps) that can be performed with any suitable order and/or any combination.

At operation 502, a memory cell is formed (e.g., the memory cell 124 of FIG. 1), where forming the memory cell include form a first transistor (e.g., the first vertical transistor 126a of FIG. 1) and a second transistor (e.g., the second vertical transistor 126b of FIG. 1).

At operation 504, a first transistor is formed transistor (e.g., the first vertical transistor 126a of FIG. 1), where the first transistor includes a first semiconductor body (e.g., the first semiconductor body 130a of FIG. 1) extending along a first direction (e.g., the Z direction); a first conductive structure (e.g., the first conductive structure 136a of FIG. 1) that is connected to the first semiconductor body; and a first gate structure (e.g., the gate structure 132a of FIG. 1) that extends along the first direction, where the first semiconductor body is between the first conductive structure and the first gate structure along a second direction (e.g., the X direction) perpendicular to the first direction.

At operation 506, a second transistor (e.g., the second vertical transistor 126b of FIG. 1) is formed, where the second transistor includes a second semiconductor body (e.g., the second semiconductor body 130b of FIG. 1) extending along the first direction; and a second conductive structure (e.g., the second conductive structure 136b of FIG. 1), where the second conductive structure is connected to the first conductive structure.

In some implementations, the second transistor of the memory cell includes a second gate structure (e.g., the gate structure 132b of FIG. 1), where the method includes providing a semiconductor substrate having a first dielectric layer (e.g., the substrate 302 of FIG. 3A), a second conductive layer (e.g., the first conductive layer 304 of FIG. 3A), and a second dielectric layer (e.g., the first semiconductor layer 306 of FIG. 3A), where the second conductive layer is between the first dielectric layer and the second dielectric layer; etching a first portion of the second dielectric layer along the first direction to form a first trench (e.g., the first trenches 308 of FIG. 3B), where the first trench extends along a third direction (e.g., the Z direction) perpendicular to the first direction and the second direction; depositing a semiconductor layer, a third dielectric layer, and a third conductive layer on an inner wall of the first trench; filling the first trench with a first dielectric material; etching a second portion of the second dielectric layer along the first direction to from second trenches (e.g., the second trenches 324 of FIG. 3J), where the second trenches are separated from the second conductive layer by a remaining portion of the second dielectric layer along the first direction, and where the second trenches extend along the third direction; depositing a second dielectric material on an inner wall of the second trenches to form a fourth dielectric layer (e.g., the second dielectric layer 328 of FIG. 3K); depositing a conductive material on a portion of the fourth dielectric layer to form the first gate structure and the second gate structure of the memory cell; and filling the second trenches with a third dielectric material.

In some implementations, the first semiconductor body and the second semiconductor body are isolated from each other, where the method further includes etching a portion of the semiconductor layer on a bottom of the first trench to separate the semiconductor layer into the first semiconductor body and the second semiconductor body of the memory cell, where the second conductive layer is in contact with the first semiconductor body, the second semiconductor body and the third dielectric layer along the first direction.

In some implementations, the memory cell further includes an interconnect layer (e.g., the interconnect layer 342 of FIG. 3T), where forming the interconnect layer includes etching a first portion of the first semiconductor body, a portion of the third conductive layer, a portion of the third dielectric layer, and a portion of the fourth dielectric layer along the first direction to form a first hole (e.g., the third trenches 340 of FIG. 3S); depositing a conductive material in the first hole to from the interconnect layer, where the interconnect layer is in contact with the first semiconductor body and the second conductive layer along the first direction; and filling a fourth dielectric material into the first hole to form a separation layer (e.g., the third dielectric layer 344 of FIG. 3T).

In some implementations, the process further includes etching a second portion of the second conductive layer along the first direction to form a second hole (e.g., the fourth trench 346 of FIG. 3V); filling the second hole with a fifth dielectric material to form a first isolation structure (e.g., second dielectric structure 347 of FIG. 3W); and depositing a first conductive layer (e.g., the fourth conductive layer 348 of FIG. 3Y) on an end of the semiconductor substrate to form a third conductive layer, where the third conductive layer is in contact with the second semiconductor body, the first isolation structure, and the separation layer along the first direction.

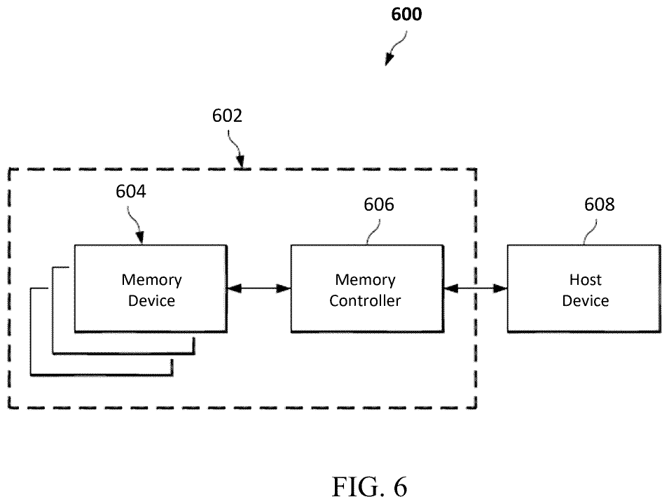

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as 3D memory device depicted in FIGS. 1-2C. In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate. The terms “operation” and “step” can be used interchangeably to describe a process.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What the claim is:

1. A semiconductor device, comprising:
a memory cell, wherein the memory cell comprises:
a first transistor, wherein the first transistor comprises:
a first semiconductor body extending along a first direction;
a first conductive structure that is connected to the first semiconductor body;
a first gate structure that extends along the first direction, wherein the first semiconductor body is between the first conductive structure and the first gate structure along a second direction perpendicular to the first direction; and
a second transistor, wherein the second transistor comprises:
a second semiconductor body extending along the first direction; and
a second conductive structure, wherein the second conductive structure is connected to the first conductive structure.

2. The semiconductor device of claim 1, wherein the second transistor further comprises:
a second gate structure that extends along the first direction, wherein the second semiconductor body is between the second conductive structure and the second gate structure along the second direction.

3. The semiconductor device of claim 2, wherein the first conductive structure and the second conductive structure are between the first semiconductor body and the second semiconductor body along the second direction, and
wherein the first semiconductor body and the second semiconductor body are between the first gate structure and the second gate structure along the second direction.

4. The semiconductor device of claim 1, wherein the first semiconductor body and the second semiconductor body comprise a metal oxide.

5. The semiconductor device of claim 2, wherein a length of the first conductive structure is greater than a length of the first gate structure along the first direction, and wherein a length of the second conductive structure is greater than a length of the second gate structure along the first direction.

6. The semiconductor device of claim 1, wherein the first transistor further comprises an interconnect layer extending along the second direction,
wherein the interconnect layer is in contact with the first conductive structure and the first semiconductor body along the first direction.

7. The semiconductor device of claim 6, wherein the semiconductor device further comprises a first conductive layer stacked on a first end of the second semiconductor body,
wherein the first conductive layer is isolated from the interconnect layer by a separation layer, and
wherein the first conductive layer is in contact with the second semiconductor body.

8. The semiconductor device of claim 7, wherein the second conductive structure is isolated from the first conductive layer by a first isolation structure along the first direction.

9. The semiconductor device of claim 7, wherein the semiconductor device further comprises a second conductive layer extending along the second direction, wherein the second conductive layer is stacked on a second end of the second semiconductor body,
wherein the first end and the second end of the second semiconductor body are on opposite end of the memory cell along the first direction, and
wherein the first semiconductor body and the second semiconductor body are in contact with the second conductive layer along the first direction.

10. The semiconductor device of claim 9, wherein the semiconductor device comprises an array of memory cells, and wherein the array of the memory cells comprises rows extending along the second direction and columns extending along a third direction perpendicular to the first direction and the second direction.

11. The semiconductor device of claim 10, wherein the semiconductor device further comprises:
one or more second isolation structures extending along the second direction;
a first word line that extends through the one or more second isolation structures along the third direction, wherein the first word line comprises one or more first gate structures of one or more memory cells; and
a second word line that extends through the one or more second isolation structures along the third direction, wherein the second word line comprises one or more second gate structures of the one or more memory cells.

12. The semiconductor device of claim 11, wherein the rows of the array of the memory cells are separated from each other by a second isolation structure of the one or more second isolation structures.

13. The semiconductor device of claim 12, wherein second conductive layer comprises one or more bit lines that extend along the second direction, and wherein the one or more bit lines are separated by the one or more second isolation structures along the third direction.

14. The semiconductor device of claim 10, wherein the semiconductor device further comprises a stack of the array of the memory cells, wherein the array of the memory cells are stacked on top of each other along the first direction.

15. A method of forming a semiconductor device, comprising:
forming a memory cell, wherein forming the memory cell comprises:
forming a first transistor, wherein the first transistor comprises:
a first semiconductor body extending along a first direction;
a first conductive structure that is connected to the first semiconductor body;
a first gate structure that extends along the first direction, wherein the first semiconductor body is between the first conductive structure and the first gate structure along a second direction perpendicular to the first direction; and
forming a second transistor, wherein the second transistor comprises:
a second semiconductor body extending along the first direction; and
a second conductive structure, wherein the second conductive structure is connected to the first conductive structure.

16. The method of claim 15, wherein the second transistor of the memory cell comprises a second gate structure, wherein the method comprises:
providing a semiconductor substrate having a first dielectric layer, a second conductive layer, and a second dielectric layer, wherein the second conductive layer is between the first dielectric layer and the second dielectric layer along the first direction;
etching a first portion of the second dielectric layer along the first direction to form a first trench, wherein the first trench extends along a third direction perpendicular to the first direction and the second direction;
depositing a semiconductor layer, a third dielectric layer, and a third conductive layer on an inner wall of the first trench;
filling the first trench with a first dielectric material;
etching a second portion of the second dielectric layer along the first direction to from second trenches, wherein the second trenches are separated from the second conductive layer by a remaining portion of the second dielectric layer along the first direction, and wherein the second trenches extend along the third direction;
depositing a second dielectric material on an inner wall of the second trenches to form a fourth dielectric layer;
depositing a conductive material on a portion of the fourth dielectric layer to form the first gate structure and the second gate structure of the memory cell; and
filling the second trenches with a third dielectric material.

17. The method of claim 16, wherein the first semiconductor body and the second semiconductor body are isolated from each other, wherein the method further comprises:
etching a portion of the semiconductor layer on a bottom of the first trench to separate the semiconductor layer into the first semiconductor body and the second semiconductor body of the memory cell,
wherein the second conductive layer is in contact with the first semiconductor body, the second semiconductor body and the third dielectric layer along the first direction.

18. The method of claim 17, wherein the memory cell further comprises an interconnect layer, wherein forming the interconnect layer comprises:
etching a first portion of the first semiconductor body, a portion of the third conductive layer, a portion of the third dielectric layer, and a portion of the fourth dielectric layer along the first direction to form a first hole;
depositing a conductive material in the first hole to from the interconnect layer, wherein the interconnect layer is in contact with the first semiconductor body and the second conductive layer along the first direction; and
filling a fourth dielectric material into the first hole to form a separation layer.

19. The method of claim 18, further comprising:
etching a second portion of the second conductive layer along the first direction to form a second hole;
filling the second hole with a fifth dielectric material to form a first isolation structure; and
depositing a first conductive layer on an end of the semiconductor substrate to form a third conductive layer, wherein the third conductive layer is in contact with the second semiconductor body, the first isolation structure, and the separation layer along the first direction.

20. A memory system, comprising:
a memory device; and
a memory controller coupled to the memory device and configured to control the memory device,
wherein the memory device comprises:
a memory cell, wherein the memory cell comprises:
a first transistor, wherein the first transistor comprises:
a first semiconductor body extending along a first direction;
a first conductive structure that is connected to the first semiconductor body;
a first gate structure that extends along the first direction, wherein the first semiconductor body is between the first conductive structure and the first gate structure along a second direction perpendicular to the first direction; and
a second transistor, wherein the second transistor comprises:
a second semiconductor body extending along the first direction; and
a second conductive structure, wherein the second conductive structure is connected to the first conductive structure.
